(19) United States
(12) Patent Application Publication
(10) Pub. No.: US 2013/0327394 A1
(43) Pub. Date: Dec. 12, 2013

(54) Electroconductive Paste and Solar Cell

(71) Applicant: MURATA MANUFACTURING CO., LTD., Nagaokakyo-Shi (JP)

(72) Inventors: Masumi Noguchi, Nagakakyo-Shi (JP); Yoshihiro Kawaguchi, Nagaokakyo-Shi (JP); Shodo Takei, Nagaokakyo-Shi (JP); Kosuke Nishino, Nagaokakyo (JP)

(73) Assignee: MURATA MANUFACTURING CO., LTD., Nagaokakyo-Shi (JP)

(21) Appl. No.: 13/966,331

(22) Filed: Aug. 14, 2013

Related U.S. Application Data
(63) Continuation of application No. PCT/JP2012/052705, filed on Feb. 7, 2012.

(30) Foreign Application Priority Data
Feb. 18, 2011 (JP) 2011-033352

(51) Int. Cl. H01L 31/0224

(52) U.S. Cl. CPC H01L 31/022425
USPC 136/256; 252/514

(57) ABSTRACT

An electroconductive paste that contains an Ag powder, glass frit and an organic vehicle. The glass frit is of non-lead type and contains at least B, Bi and Si and the molar ratio of B to Si is 0.4 or less, and the molar content of Bi in the glass frit is 20 to 30 mol %, and a D₉₀ diameter of the glass frits is 5 μm or less. A light-receiving surface electrode is formed using this electroconductive paste on a surface of a semiconductor substrate to form a solar cell.

### CROSS REFERENCE TO RELATED APPLICATIONS

The present application is a continuation of International application No. PCT/JP2012/052705, filed Feb. 7, 2012, which claims priority to Japanese Patent Application No. 2011-033352, filed Feb. 18, 2011, the entire contents of each of which are incorporated herein by reference.

### FIELD OF THE INVENTION

The present invention relates to an electroconductive paste and a solar cell, and more particularly to an electroconductive paste suitable for forming an electrode of a solar cell and a solar cell manufactured by using the electroconductive paste.

### BACKGROUND OF THE INVENTION

A solar cell typically has a light-receiving surface electrode of a predetermined pattern formed on one principal surface of a semiconductor substrate. Also, an antireflection film is formed on the semiconductor substrate excluding the light-receiving surface electrode, and the reflection loss of incident solar light is suppressed by the antireflection film, whereby the conversion efficiency of solar light into electric energy is improved.

The light-receiving surface electrode is formed typically in the following manner using an electroconductive paste. That is, the electroconductive paste contains an electroconductive powder, a glass frit, and an organic vehicle, and the electroconductive paste is applied onto the surface of an antireflection film formed on a semiconductor substrate, so as to form an electroconductive film having a predetermined pattern. Subsequently, in a firing process, the glass frit is fused, and the antireflection film located under the electroconductive film is decomposed and removed, whereby the electroconductive film is sintered to form a light-receiving surface electrode, and the light-receiving surface electrode and the semiconductor substrate are bonded and electrically conducted with each other.

A method of decomposing and removing the antireflection film in a firing process to bond the semiconductor substrate and the light-receiving surface electrode with each other in this manner is referred to as a fire-through (fire-through), and the conversion efficiency of a solar cell is largely dependent on the fire-through property. In other words, it is known that, when the fire-through property is insufficient, the conversion efficiency decreases, thereby causing inferior basic performance as a solar cell.

Also, in this kind of a solar cell, it is thought to be preferred to use a low-softening point glass frit in order to enhance adhesive strength between the light-receiving surface electrode and the semiconductor substrate.

As the low-softening point glass frits, heretofore, lead-based glass frits have been used, but the emergence of new materials in place of the lead-based glass frit is desired because an environmental burden of lead is large.

From such a viewpoint, Patent Document 1 proposes an electroconductive paste in which a softening point of the glass frit is 570 to 760° C., the glass frit contains B₂O₃ and SiO₂ in such a way that a molar ratio of B₂O₃ to SiO₂ is 0.3 or less, and Bi₂O₃ is contained in an amount below 20 mol %.

Bi₂O₃ is a component effective for promoting the fire-through property, but when the content of Bi₂O₃ in the glass frit is more than 20 mol %, a softening point is lowered to decrease glass viscosity. As a result of this, a glass component excessively builds up at an interface (hereinafter, this phenomenon is referred to as a “glass accumulation at an interface”) between the light-receiving surface electrode and the semiconductor substrate to increase contact resistance.

Then, Patent Document 1 aims at attaining a solar cell in which contact resistance between the light-receiving surface electrode and the semiconductor substrate is low even when using a non-lead type electroconductive paste not containing Pb by suppressing the content of Bi₂O₃ below 20 mol %.
Patent Document 1: WO 2007/102287 (claim 2, paragraph [0016], [0036])

### SUMMARY OF THE INVENTION

However, in Patent Document 1, a molar content of Bi₂O₃, which is effective for improving a fire-through property, is suppressed below 20 mol % in order to avoid the formation of the glass accumulation at an interface. Therefore, when an electrode width of the light-receiving surface electrode is as fine as 100 μm or less, a good fire-through property cannot be adequately ensured, resulting in the increase in contact resistance, and there is a possibility that cell characteristics of a solar cell may be deteriorated.

The present invention has been made in view of such circumstances, and it is an object of the present invention to provide a non-lead type electroconductive paste, which can ensure a good conducting property between a semiconductor substrate and a light-receiving surface electrode even when an electrode width of the light-receiving surface electrode is fine, and a solar cell manufactured by using this electroconductive paste.

Since Bi₂O₃ is a component effective for promoting the fire-through property as described above, it is thought to be desirable to increase the molar content of Bi₂O₃ to 20 mol % or more in order to achieve an adequate fire-through property even when the electrode width of the light-receiving surface electrode is small.

Then, the present inventors made earnest investigations in order to avoid the occurrence of the glass accumulation at an interface associated with the decrease in a softening point while increasing the molar content of Bi₂O₃ to 20 mol % or more in a Si—B—Bi-based glass frit, and consequently they obtained findings that the glass frits can be dispersed uniformly or approximately uniformly in the electroconductive paste by setting a 90% cumulative grain diameter from a fine grain side to 5 μm or less in a cumulative grain size distribution of glass frits, and thereby the formation of the glass accumulation at an interface can be suppressed even if the electroconductive paste is fired when the molar content of Bi₂O₃ is in the range of 20 to 30 mol %.

Further, it is found that by setting the molar ratio of B₂O₃ to SiO₂ to 0.4 or less, the electroconductive powder can be easily deposited on a semiconductor substrate, and also thereby, the contact resistance can be effectively reduced, and the conducting property between the light-receiving surface electrode and the semiconductor substrate can be improved.

The present invention was made based on such findings, and the electroconductive paste of the present invention is a paste for forming an electrode of a solar cell, comprising an electroconductive powder, glass frits, and an organic vehicle, wherein the glass frit does not contain Pb and contains at least B, Bi and Si, the molar ratio of B to Si is 0.4 or less in terms of SiO₂ and B₂O₃, the molar content of Bi in the glass frit is 20 to 30 mol % in terms of Bi₂O₃, and a 90% cumulative grain diameter from a fine grain side (hereinafter, referred to as a “D₉₀ diameter”) in a cumulative grain size distribution of the glass frits is 5 μm or less.

Thereby, formation of the glass accumulation at an interface can be suppressed and a fire-through property of the antireflection film can be improved, and it becomes possible to obtain a solar cell having a good conducting property and high conversion efficiency, in which the contact resistance between the light-receiving surface electrode and the semiconductor substrate is reduced.

Further, the present inventors made further earnest investigations, and consequently, it has been found out that, by containing ZnO having a specific surface area of 6.5 m²/g or more, a further improvement of the fire-through property can be achieved.

In other words, the electroconductive paste of the present invention preferably contains ZnO having a specific surface area of 6.5 m²/g or more.

Thereby, a melt glass with a proper size flows in the interface without generating the glass accumulation at an interface, and therefore adhesive strength of the interface is improved to enable a further reduction of the contact resistance and a further improvement of a fire-through property.

Moreover, as a result of further earnest investigations made by the present inventors, it has been also found out that when the electroconductive paste contains ZnO having a specific surface area of 6.5 m²/g or more, the further improvement of the fire-through property can be achieved, as described above, and on the other hand, a soldering property is impaired when the specific surface area exceeds 12.5 m²/g.

Accordingly, in the electroconductive paste of the present invention, the ZnO preferably has a specific surface area of 12.5 m²/g or less, and more preferably has a specific surface area of 9.5 m²/g or less.

Thereby, it becomes possible to attain desired low contact resistance without causing deterioration of a soldering property.

Further, it is thought that a complicated oxidation-reduction reaction occurs during firing at an interface between the semiconductor substrate and the light-receiving surface electrode. The basicity which is a physical constant of a material is an important measure in considering an oxidation-reduction reaction of a melt glass. Further, since a good fire-through property is achieved in conventional lead type electroconductive pastes, it is preferred to contain an alkaline-earth metal oxide having basicity similar to Pb, particularly BaO, and further it is more preferred to contain an alkaline-earth metal oxide in an amount of 5 mol % or more.

That is, in the electroconductive paste of the present invention, the glass frit preferably contains an alkaline-earth metal oxide.

Also, in the electroconductive paste of the present invention, the alkaline-earth metal oxide is particularly preferably BaO.

Further, in the electroconductive paste of the present invention, the content of the alkaline-earth metal oxide is more preferably 5 mol % or more.

As described above, when the electroconductive paste contains these alkaline-earth metal oxides, the contact resistance can be further lowered, and a better desired fire-through property can be achieved.

Further, in the electroconductive paste of the present invention, the electroconductive powder is preferably an Ag powder.

Further, the solar cell of the present invention is characterized in that an antireflection film and an electrode which penetrates through the antireflection film are formed on one principal surface of a semiconductor substrate, and the electrode is formed by sintering the electroconductive paste according to any one of the above.

Thereby, even though a non-lead type electroconductive paste is used, it is possible to reduce the contact resistance between the light-receiving surface electrode and the semiconductor substrate for a light-receiving surface electrode having a fine electrode width, and it becomes possible to obtain a solar cell having a good conducting property and high conversion efficiency.

In accordance with the electroconductive paste of the present invention, since the paste contains an electroconductive powder such as an Ag powder, glass frits and an organic vehicle, and the glass frit does not contain Pb and contains at least B, Bi and Si and the molar ratio of B to Si is 0.4 or less in terms of SiO₂ and B₂O₃, and the molar content of Bi in the glass frit is 20 to 30 mol % in terms of Bi₂O₃, and a D₉₀ diameter of the glass frits is 5 μm or less, the formation of the glass accumulation at an interface can be suppressed and a fire-through property of the antireflection film can be improved to enable to obtain a solar cell having a good conducting property and high conversion efficiency in which the contact resistance between the light-receiving surface electrode and the semiconductor substrate is reduced.

Also, in accordance with the solar cell of the present invention, since an antireflection film and an electrode which penetrates through the antireflection film are formed on one principal surface of a semiconductor substrate, and the electrode is formed by sintering the electroconductive paste according to any one of the above, solar cells having a good conducting property and high conversion efficiency, which can reduce contact resistance between the light-receiving surface electrode and the semiconductor substrate for a light-receiving surface electrode having a fine electrode width even when a non-lead type electroconductive paste is used, can be obtained.

### BRIEF EXPLANATION OF THE DRAWINGS

FIG. 1 is a cross-sectional view of a main part showing one embodiment of a solar cell manufactured by using an electroconductive paste according to the present invention.

FIG. 2 is an enlarged plan view schematically showing a light-receiving surface electrode side.

FIG. 3 is an enlarged plan view schematically showing a backside electrode side.

FIG. 4 is an enlarged sectional view of a main part around an electroconductive film containing glass frits having variations in a grain size.

FIG. 5 is an enlarged sectional view of a main part around a light-receiving surface electrode in the case of firing the electroconductive film in FIG. 4.

FIG. 6 is an enlarged sectional view of a main part around an electroconductive film containing glass frits in which a grain size is adjusted to a predetermined grain size or less.

FIG. 7 is an enlarged sectional view of a main part around a light-receiving surface electrode in the case of firing the electroconductive film in FIG. 6.

FIG. 8 is an enlarged sectional view of a main part around a light-receiving surface electrode in the case of containing ZnO grains having a small specific surface area.

FIG. 9 is an enlarged sectional view of a main part around a light-receiving surface electrode in the case of containing ZnO grains having a large specific surface area.

FIG. 10 is a plan view schematically showing an electrode prepared in an example.

### DETAILED DESCRIPTION OF THE INVENTION

Next, an embodiment of the present invention will be described in detail.

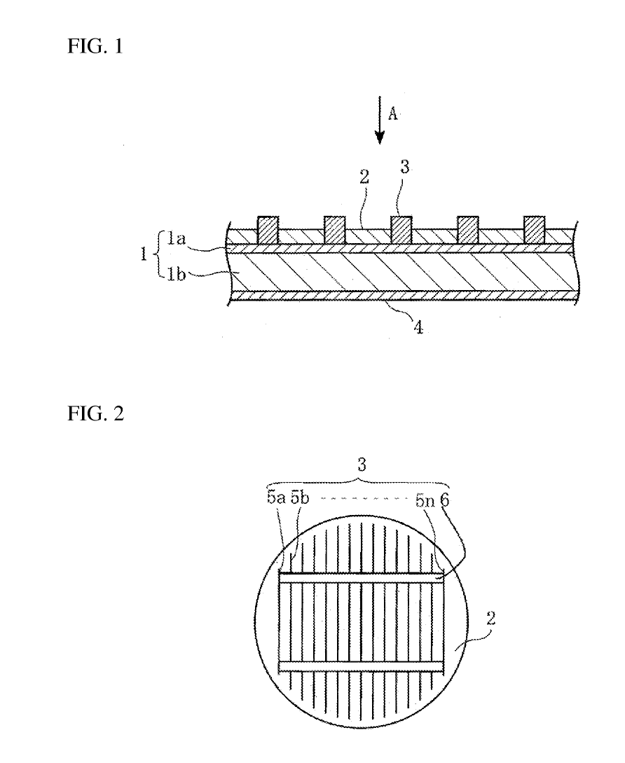

FIG. 1 is a cross-sectional view of a main part illustrating one embodiment of a solar cell manufactured by using an electroconductive paste of the present invention.

In this solar cell, an antireflection film 2 and a light-receiving surface electrode 3 are formed on one principal surface of a semiconductor substrate 1 containing Si as a major component, and a backside electrode 4 is formed on the other principal surface of the semiconductor substrate 1.

The semiconductor substrate 1 has a p-type semiconductor layer 1b and an n-type semiconductor layer 1a, and the n-type semiconductor layer 1a is formed on the upper surface of the p-type semiconductor layer 1b. The semiconductor substrate 1 can be obtained, for example, by diffusing impurities into one principal surface of a single crystal or polycrystal p-type semiconductor layer 1b to form a thin n-type semiconductor layer 1a; however, the structure and the method of production thereof are not particularly limited as long as the n-type semiconductor layer 1a is formed on the upper surface of the p-type semiconductor layer 1b. Also, as the semiconductor substrate 1, a semiconductor substrate having a structure such that the thin p-type semiconductor layer 1b is formed on one principal surface of the n-type semiconductor layer 1a or a semiconductor substrate having a structure such that both of the p-type semiconductor layer 1b and the n-type semiconductor layer 1a are formed on a part of one principal surface of the semiconductor substrate 1 may be used. In any case, the electroconductive paste of the present invention can be effectively used on a surface as long as the surface is the principal surface of the semiconductor substrate 1 on which the antireflection film 2 is formed.

Here, in FIG. 1, the surface of the semiconductor substrate 1 is depicted to be flat; however, the surface is formed to have a fine irregularity structure in order to confine solar light effectively into the semiconductor substrate 1.

The antireflection film 2 is formed of an insulating material such as silicon nitride (SiNₓ) and suppresses the reflection of solar light shown by an arrow A to the light-receiving surface, so as to guide solar light quickly and efficiently to the semiconductor substrate 1. The material composing this antireflection film 2 is not limited to silicon nitride described above, so that other insulating materials, for example, silicon oxide or titanium oxide, may be used, and also two or more insulating materials may be used in combination. Also, any one of single crystal Si and polycrystal Si may be used as long as it is a crystal Si type material.

The light-receiving surface electrode 3 is formed on the semiconductor substrate 1 so as to penetrate through the antireflection film 2. This light-receiving surface electrode 3 is formed by using screen printing or the like, applying an electroconductive paste of the present invention described later onto the semiconductor substrate 1 to prepare an electroconductive film, and firing the resultant. That is, in the firing process of forming the light-receiving surface electrode 3, the antireflection film 2 under the electroconductive film is decomposed and removed to give a fire-through, and this allows that the light-receiving surface electrode 3 is formed on the semiconductor substrate 1 in the form of penetrating through the antireflection film 2.

Specifically, as shown in FIG. 2, the light-receiving surface electrode 3 is formed in such a manner that numerous finger electrodes 5a, 5b, . . . 5n are disposed in parallel in a comb-teeth shape, and a bus bar electrode 6 is disposed to intersect the finger electrodes 5a, 5b, . . . 5n, whereby the finger electrodes 5a, 5b, . . . 5n are electrically connected to the bus bar electrode 6. Further, the antireflection film 2 is formed in a remaining region other than the part where the light-receiving surface electrode 3 is disposed. In this manner, the electric power generated in the semiconductor substrate 1 is collected by the finger electrode 5n and extracted to the outside by the bus bar electrode 6.

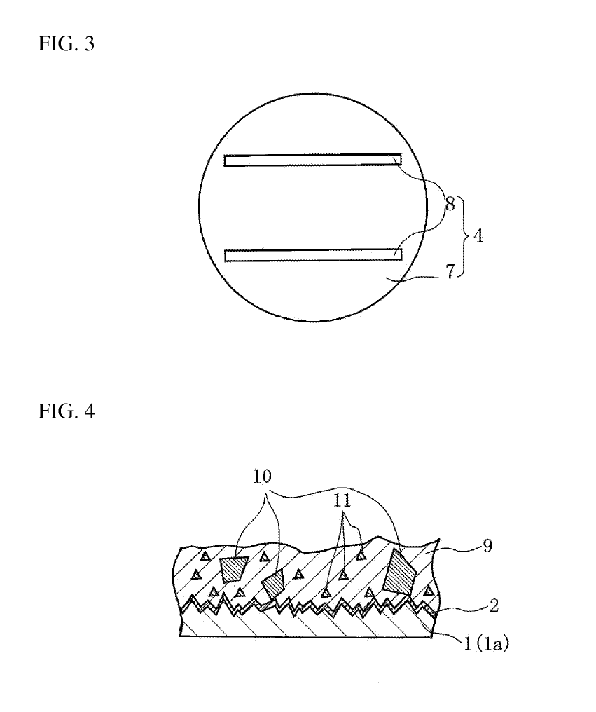

Referring to FIG. 3, the backside electrode 4 specifically includes a collecting electrode 7 made of Al or the like formed on the back surface of the p-type semiconductor layer 1b and an extraction electrode 8 made of Ag or the like formed on the back surface of the collecting electrode 7 and electrically connected to the collecting electrode 7. Further, the electric power generated in the semiconductor substrate 1 is collected to the collecting electrode 7, and the electric power is extracted by the extraction electrode 8.

Next, the electroconductive paste of the present invention for forming the light-receiving surface electrode 3 will be described in detail.

The electroconductive paste of the present invention contains an electroconductive powder, non-lead type glass frits not containing Pb, and an organic vehicle.

Further, the glass frit contains at least B, Bi and Si and satisfies the following equations (1) to (3).

α/β0.4 (1)

20 mol %≦γ≦30 mol % (2)

D₉₀ diameter≦5 μm (3)

Herein, α represents the molar content of B₂O₃ in the glass frit, β represents the molar content of SiO₂ in the glass frit, and γ represents the molar content of Bi₂O₂ in the glass frit.

That is, the electroconductive paste of the present invention includes non-lead type glass frits containing at least B, Bi and Si, and in the electroconductive paste, the molar ratio α/β of B₂O₃ to SiO₂ is set to 0.4 or less, the molar content of Bi₂O₃ in the glass frit is set to 20 to 30 mol %, and the D₉₀ diameter is set to 5 μm or less. Further, thereby, the glass frits are not present in segregation in the electroconductive paste and can be dispersed uniformly or approximately uniformly in the electroconductive paste. Accordingly, a large aggregated melt glass is not formed during firing. Consequently, a glass accumulation at an interface is not generated, and a fire-through property can be improved even when an electrode width of the light-receiving surface electrode 3 is as fine as 100 μm or less. Thereby, contact resistance between the semiconductor substrate 1 and the light-receiving surface electrode 3 can be reduced to increase conversion efficiency.

Hereinafter, the reason why the glass frit is allowed to satisfy the above equations (1) to (3) will be described.

(1) Molar Ratio α/β of B₂O₃ to SiO₂

Glass is composed of a net-like oxide which becomes non-crystalline to form a network structure, a modified oxide which modifies the net-like oxide to make it non-crystalline, and an intermediate oxide intermediate between both oxides. Among these oxides, both of SiO₂ and B₂O₃ act as a net-like oxide and are important constituent components.

Further, in the electroconductive paste for forming an electrode of a solar cell, since the electroconductive powder is dissolved in the glass frit during firing an electroconductive film, and the dissolved electroconductive powder is reduced on the semiconductor substrate 1 to be deposited as a metal grain, the formation of electrical contact between the electroconductive powder and the semiconductor substrate 1 is promoted.

However, when a molar ratio α/β between the molar content α of B₂O₃ and the molar content β of SiO₂ is more than 0.4, the molar content of B₂O₃ is excessive so that an amount of the electroconductive powder to be dissolved in the glass frit is increased, but the electroconductive powder dissolved in the glass frit is hardly deposited on the semiconductor substrate 1 to impair the formation of electrical contact on the contrary.

Thus, in the present embodiment, the molar ratio α/β of B₂O₃ to SiO₂ is set to 0.4 or less.

(2) Molar Content γ of Bi₂O₃

Since Bi₂O₃ has the action of adjusting flowability of glass as a modified oxide and further promotes a fire-through property, Bi₂O₃ is preferably contained in the glass frit, particularly, in the case of a non-lead type electroconductive paste.

However, when the molar content γ of Bi₂O₃ in the glass frit is less than 20 mol %, a softening point is increased. Hence, this contributes to suppress the formation of the glass accumulation at an interface, but the deterioration of a fire-through property is remarkable when the electrode width is fine, and there is a possibility of resulting in the increase in contact resistance.

So, in the present embodiment, as described later, the occurrence of the glass accumulation at an interface is suppressed by adjusting grain sizes of glass frits, while the molar content γ of Bi₂O₃ is set to 20 mol % or more, and thereby the good fire-through property is ensured even when the electrode width is as fine as 100 μm or less.

However, when the molar content γ of Bi₂O₃ is more than 30 mol %, a softening point is excessively lowered, and therefore it becomes difficult to suppress the occurrence of the glass accumulation at an interface even by adjusting grain sizes of glass frits. That is, when the molar content γ of Bi₂O₃ is more than 30 mol %, a softening point is excessively lowered to cause glass viscosity to decrease excessively, and therefore flowability of the glass frit may be increased to generate the glass accumulation at an interface, resulting in an increase in contact resistance. Also when the molar content γ of Bi₂O₃ is more than 30 mol %, it is not preferred since Bi₂O₃ may be diffused into the semiconductor substrate 1.

Thus, in the present embodiment, the molar content γ of Bi₂O₃ in the glass frit is set to 20 to 30 mol %.

(3) D₉₀ Diameter

In a solar cell, as described above, the light-receiving surface electrode 3 is formed on the semiconductor substrate 1 by applying the antireflection film 2 onto the semiconductor substrate 1, then applying the electroconductive paste containing the glass frit, and performing a fire-through during a firing process. That is, a melt glass formed by melting the glass frit breaks the antireflection film 2, and decomposes and removes the antireflection film 2 to perform a fire-through. Accordingly, in order to suppress the formation of the glass accumulation at an interface, it is preferred to avoid the formation of a large aggregated melt glass, and to this end, it is thought to be effective that grain sizes of glass frits are made to be fine to disperse the glass frits uniformly or approximately uniformly in the electroconductive paste.

For example, when there are large variations in grain size of the glass frit, a glass frit having a large grain size and a glass frit having a small grain size coexist in the electroconductive paste.

Further, as shown in FIG. 4, the antireflection film 2 is formed on the surface, having the fine irregularity structure, of an n-type semiconductor layer 1a of the semiconductor substrate 1, the electroconductive paste is applied onto the surface of the antireflection film 2, and a dried electroconductive film 9 is formed. In this case, a glass frit 10 having a large grain size and a glass frit 11 having a small grain size coexist in the electroconductive film 9.

When the electroconductive film 9 is passed through a fast firing furnace to be fired, the glass frit 10 having a large grain size and the glass frit 11 having a small grain size are gathered to become a large aggregated melt glass, as shown in FIG. 5. Then, the antireflection film 2 on the n-type semiconductor layer 1a is decomposed and removed, but glass accumulation parts at an interface 12a and 12b are formed at a portion where the antireflection film 2 is decomposed and removed. On the other hand, a glass component is less between the glass accumulation part at an interface 12a and the glass accumulation part at an interface 12b, and therefore the antireflection film 2 does not undergo the fire-through and remains to form a remaining part 13 of antireflection film. That is, though the antireflection film 2 is decomposed and removed at the glass accumulation parts at an interface 12a and 12b, a contacting property between the electroconductive powder and the semiconductor substrate 1 is deteriorated to increase the contact resistance due to the glass accumulation parts at an interface 12a and 12b. On the other hand, in the remaining part 13, the contact resistance is increased since the antireflection film 2 remains without undergoing the fire-through.

As described above, when the glass frit 10 having a large grain size is mixed in the electroconductive paste, there is a possibility that the fire-through property is deteriorated, resulting in the reduction of a conducting property between the light-receiving surface electrode 3 and the semiconductor substrate 1.

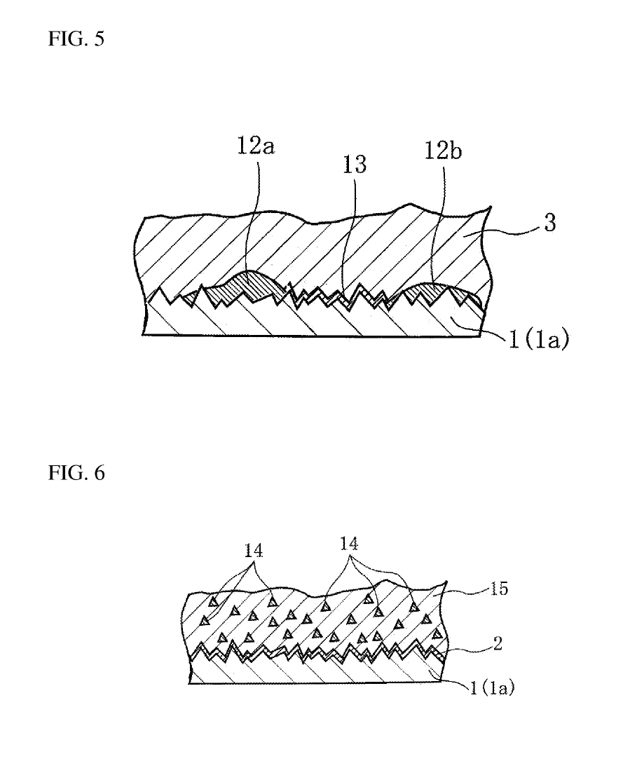

On the other hand, FIG. 6 is an enlarged sectional view of a main part around an electroconductive film containing only glass frits in which a grain size is adjusted to a predetermined grain size or less.

That is, only glass frits 14 in which a grain size is adjusted to a predetermined grain size or less is contained in the electroconductive paste, and the glass frits are uniformly or approximately uniformly dispersed in a step of being kneaded with an organic vehicle. Accordingly, the glass frits 14 are present in a state of being uniformly or approximately uniformly dispersed also in the electroconductive film 15.

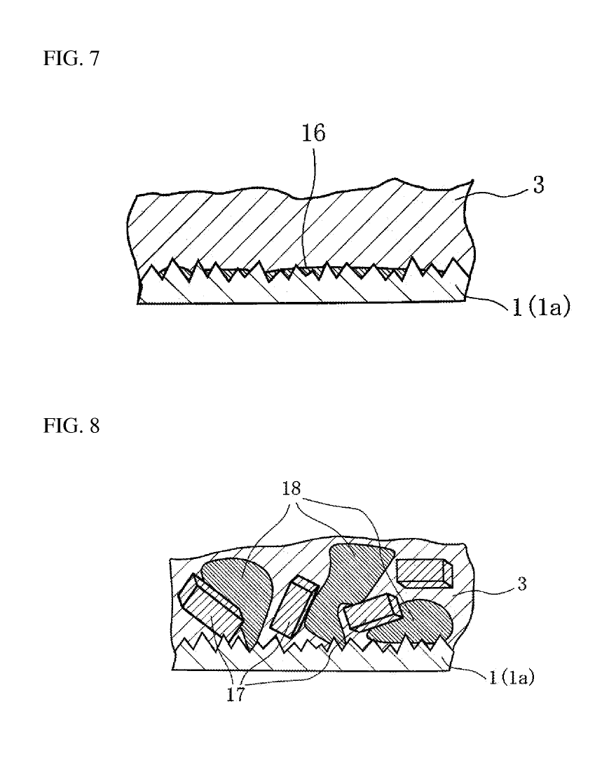

When the electroconductive film 15 is passed through a fast firing furnace to be fired, as shown in FIG. 7, even though the glass frits 14 are melted, a melt glass 16 is not segregated and does not form the glass accumulation at an interface. Moreover, there is no region where extremely less glass frits are present, and a good fire-through property can be ensured. Thereby, the contact resistance between the light-receiving surface electrode 3 and the semiconductor substrate 1 can be reduced.

As a predetermined grain size for dispersing the glass frits uniformly or approximately uniformly in the electroconductive paste, as described above, a D₉₀ diameter needs to be set to 5 μm or less. That is, when the D₉₀ diameter is large exceeding 5 μm, the glass frits cannot be dispersed uniformly or approximately uniformly in the electroconductive paste, and the glass accumulation at an interface is generated after firing, and therefore it becomes impossible to reduce the contact resistance sufficiently.

In addition, an average grain size D₅₀ of the glass frits is not particularly limited as long as the D₉₀ diameter is 5 μm or less, and in general, the D₅₀ of about 0.1 to 1.5 μm is used.

Further, the overall content of the glass frit is not particularly limited, but it is preferably 1 to 6 parts by weight with respect to 100 parts by weight of the electroconductive powder.

As described above, in the present embodiment, since the glass frits satisfying the above equations (1) to (3) are contained in the electroconductive paste, the glass frits can be uniformly or approximately uniformly dispersed in the electroconductive paste to prevent formation of a large accumulation of melt glass during a firing process. Accordingly, the glass accumulation at an interface is not generated, and the fire-through property can be improved, and thereby the contact resistance can be reduced and the conversion efficiency can be improved.

Further, in order to improve the fire-through property further, it is preferred that 1 to 15 parts by weight of ZnO is contained in the electroconductive paste with respect to 100 parts by weight of the electroconductive powder. In a firing process, ZnO promotes decomposition and removal of the antireflection film 2 to enable a smooth fire-through and to lower the contact resistance between the light-receiving surface electrode 3 and the semiconductor substrate 1.

In particular, it is preferred that ZnO having a specific surface area of 6.5 m²/g or more is contained in the electroconductive paste, and thereby the formation of the glass accumulation at an interface of the glass frit in which the content of Bi₂O₃ is as large as 20 to 30 mol % can be suppressed to improve the fire-through property. In this case, a decomposing action of the antireflection film is thought to occur at a location where the electroconductive powder is in contact with ZnO.

FIG. 8 is an enlarged sectional view of a main part in the case of using ZnO having a specific surface area less than 6.5 m²/g, and FIG. 9 is an enlarged sectional view of a main part in the case of using ZnO having a specific surface area of 6.5 m²/g or more.

When ZnO having a specific surface area less than 6.5 m2/g is used, a grain size of a ZnO grain 17 is too large, as shown in FIG. 8, and therefore a void is generated at the interface between the semiconductor substrate 1 and the light-receiving surface electrode 3 to make it easy for a melt glass 18 to flow into between ZnO grains 17, and therefore a glass accumulation at an interface may be formed, resulting in the reduction in electrical connectivity.

On the contrary, when ZnO having a specific surface area of 6.5 m²/g or more is used, as shown in FIG. 9, since a grain size of the ZnO grain 19 is moderately small, a melt glass 20 with a proper size flows into the interface between the semiconductor substrate 1 and the light-receiving surface electrode 3 to enable to achieve good electrical contact.

However, when the specific surface area of ZnO is 12.5 m²/g or more, the specific surface area is too large and therefore a soldering property to the light-receiving surface electrode 3 may be deteriorated. When the soldering property is deteriorated as described above, a method in which the light-receiving surface electrode 3 having a two-layer structure is used and an electrode excellent in the soldering property is formed on the light-receiving surface electrode may be employed, but it is preferred to ensure the soldering property by one layer from the viewpoints of simplification of a manufacturing process and cost reduction.

Accordingly, the specific surface area of ZnO is preferably 6.5 to 12.5 m²/g, and more preferably 6.5 to 9.5 m²/g.

In addition, when the specific surface area falls within the above-mentioned range, the electroconductive paste may contain two types or more of ZnO having different specific surface areas.

Further, it is thought that a complicated oxidation-reduction reaction occurs during firing at an interface between the semiconductor substrate 1 and the light-receiving surface electrode 3. Herein, the basicity is an important measure in considering an oxidation-reduction reaction of a melt glass, and since a good fire-through property is achieved in lead type electroconductive pastes containing PbO with a basicity of 1.31, BaO (basicity: 1.56), SrO (basicity: 1.27) and CaO (basicity: 1.00), having the basicity similar to PbO, can contribute to the improvement of the fire-through property. BaO can particularly contribute to the reduction of contact resistance. Specifically, when these alkaline-earth metal oxides, particularly 5 mol % or more of BaO, are contained, the contact resistance can be reduced more effectively.

The electroconductive powder is not particularly limited as long as it is a metal powder having a good electric conductivity, but an Ag powder which can maintain a good electric conductivity without being oxidized even when the firing treatment is carried out in an ambient atmosphere may be preferably used. In addition, the shape of this electroconductive powder is not particularly limited, and the electroconductive powder may have a spherical shape, a flattened shape, or an amorphous shape, or may be a mixed powder of these.

Also, the average particle size of the electroconductive powder is not particularly limited, but the average particle size is preferably from 1.0 to 5.0 μm as converted in terms of a spherical powder in view of ensuring a desired contact point between the electroconductive powder and the semiconductor substrate 1.

The organic vehicle is prepared in such a manner that a volume ratio between a binder resin and an organic solvent is, for example, 1 to 3:7 to 9. In addition, the binder resin is not particularly limited, and for example, an ethyl cellulose resin, a nitrocellulose resin, an acrylic resin, an alkyd resin, or a combination of these may be used. Further, the organic solvent is not particularly limited, and α-terpineol, xylene, toluene, diethylene glycol monobutyl ether, diethylene glycol monobutyl ether acetate, diethylene glycol monoethyl ether, diethylene glycol monoethyl ether acetate and the like may be used singly, or may be used in combination thereof.

Also, it is preferable that, for example, one plasticizer such as di-2-ethylhexyl phthalate or dibutyl phthalate, or a combination of these is added to the electroconductive paste as required. Also, it is preferable that a rheology adjusting agent such as fatty acid amide or fatty acid is added, and further a thixotropic agent, a thickening agent, a dispersing agent or the like may be added.

This electroconductive paste can be easily produced by weighing and mixing an electroconductive powder, the glass frit described above, an organic vehicle, and various additives as required so as to attain a predetermined mixing ratio, and dispersing and kneading the resulting mixture by using a three roll mill or the like.

As described above, since the present embodiment contains an electroconductive powder such as an Ag powder, glass frits, and an organic vehicle and satisfies the above equations (1) to (3), formation of the glass accumulation at an interface can be suppressed, and a fire-through property of the antireflection film 2 can be improved to enable to obtain a solar cells having a good conducting property and high conversion efficiency in which the contact resistance between the light-receiving surface electrode and the semiconductor substrate is lowered.

Moreover, by containing ZnO having a specific surface area of 6.5 m²/g or more, a melt glass with a proper size flows into the interface without generating the glass accumulation at an interface, and adhesive strength of the interface is improved to enable further reduction of the contact resistance.

Further, when the ZnO has a specific surface area of 12.5 m²/g or less, more preferably 9.5 m²/g or less, desired low contact resistance can be achieved without causing a soldering property to deteriorate.

Further, when the glass frit contains an alkaline-earth metal oxide, preferably 5 mol % or more of BaO, the contact resistance can be further lowered, and a better desired fire-through property can be achieved.

Hence, the above-mentioned solar cell becomes a solar cell having a good conducting property and high conversion efficiency, in which the contact resistance between the light-receiving surface electrode 3 and the semiconductor substrate 1 is reduced.

In addition, the present invention is not limited to the above embodiment, and it is preferred that the glass frit contains various oxides as required.

For example, TiO₂ or ZrO₂ can improve chemical durability of glass dramatically only by being contained in a small amount in the glass frit. However, when a large amount of this oxide is contained, since there is a possibility of acting as a nucleus-generating agent, the content of TiO₂ or ZrO₂ in the glass frit is preferably set to 5 mol % or less when TiO₂ or ZrO₂ is contained in the glass frit.

Further, since alkali metal oxides such as Li₂O, Na₂O, K₂O have a function of adjusting a softening point of glass as with Bi₂O₃, it is preferred to contain appropriately the alkali metal oxide. However, when a large amount of the alkali metal oxide is contained in the glass frit, since there is a possibility of deteriorating the chemical durability of the glass frit, the content of the alkali metal oxide in the glass frit is preferably set to 10 mol % or less.

Further, since Al₂O₃ acts as an intermediate oxide of glass, it is preferred to be contained in the glass frit in an appropriate amount. By containing Al₂O₃ in the glass frit, crystallization of glass is suppressed to obtain stable amorphous glass, and chemical durability can be improved.

Next, examples of the present invention will be described specifically.

### Example 1

### Preparation of Sample

(Preparation of Glass Frit)

SiO₂, B₂O₃, Bi₂O₃, BaO, and Al₂O₃ are compounded so as to have a blending ratio by mol % shown in Table 1 to prepare glass frits A to H. Then, a softening point of each of the glass frits A to H was measured by thermal analysis by a TG-DTA (thermogravimetric-differential thermal analyzer). That is, 5 mg of each sample was put in a container made of alumina, α-alumina was used as a standard sample, and a measurement apparatus was heated according to a firing profile by which a temperature is increased at a rate of 20° C./min while supplying air to the measurement apparatus at a flow rate of 100 ml/min to prepare a TG curve and a DTA curve based on changes in weight with respect to a temperature. A softening point of each sample was measured from such the TG curve and DTA curve.

Table 1 shows the component composition of the glass frits A to H, the molar ratio α/β of B₂O₃ to SiO₂ (hereinafter, referred to as “B₂O₃/SiO₂”), and the softening point Ts.

TABLE 1

| | | | | | | B₂O₃/ | Softening |
|---|---|---|---|---|---|---|---|
| Kind of | Glass Composition (mol %) | | | | | SiO₂ | Point Ts |
| Glass Frit | SiO₂ | B₂O₃ | Bi₂O₃ | BaO | Al₂O₃ | (—) | (° C.) |
| A | 43.5 | 13.5 | 25.0 | 17.6 | 0.4 | 0.31 | 550 |
| B | 43.1 | 10.8 | 24.9 | 20.8 | 0.4 | 0.25 | 542 |
| C | 43.6 | 15.3 | 24.6 | 16.1 | 0.4 | 0.35 | 551 |
| D*¹⁾ | 40.2 | 19.3 | 25.2 | 15.3 | 0.4 | 0.48 | 560 |
| E*¹⁾ | 32.9 | 8.9 | 41.0 | 17.2 | 0.4 | 0.27 | 511 |
| F | 40.7 | 11.8 | 29.6 | 17.5 | 0.4 | 0.29 | 530 |
| G | 46.6 | 14.5 | 20.9 | 17.6 | 0.4 | 0.31 | 566 |
| H*¹⁾ | 50.1 | 13.8 | 16.8 | 18.9 | 0.4 | 0.28 | 582 |

*¹⁾indicates outside the scope of the present invention (claim 1)

As is apparent from this Table 1, in the glass frits A to C, F and G, a ratio B₂O₃/SiO₂ is 0.4 or less and the content of Bi₂O₃ is 20 to 30 mol %, and these exhibit the glass frit composition within the scope of the present invention.

On the contrary, in the glass frit D, a ratio B₂O₃/SiO₂ is 0.48 exceeding 0.4, and in the glass frit E, the content of Bi₂O₃ is 41 mol %, and in the glass frit H, the content of Bi₂O₃ is 16.8 mol %, and these do not fall within a range of 20 to 30 mol % and exhibit the glass frit composition out of the scope of the present invention.

(Preparation of Electroconductive Paste)

As an electroconductive powder, a spherical Ag powder having an average particle size of 1.6 μm and ZnO with a specific surface area of 6.6 m²/g were prepared.

Then, an organic vehicle was prepared. That is, an ethyl cellulose resin and texanol were mixed so that an ethyl cellulose resin serving as a binder resin was 10% by weight and texanol serving as an organic solvent was 90% by weight to prepare an organic vehicle.

Then, 83.0% by weight of an Ag powder, 4.6% by weight of ZnO, 2.1% by weight of glass frits, and 10.3% by weight of the organic vehicle were mixed, and the resulting mixture was mixed with a planetary mixer and then kneaded with a three roll mill to prepare electroconductive pastes of sample Nos 1 to 11.

In addition, glass frits having an average grain size (D₅₀ diameter) of 0.8 μm and a D₉₀ diameter of 2.1 to 6.2 μm were used for the glass frit to be contained in the electroconductive paste.

[Evaluation of Sample]

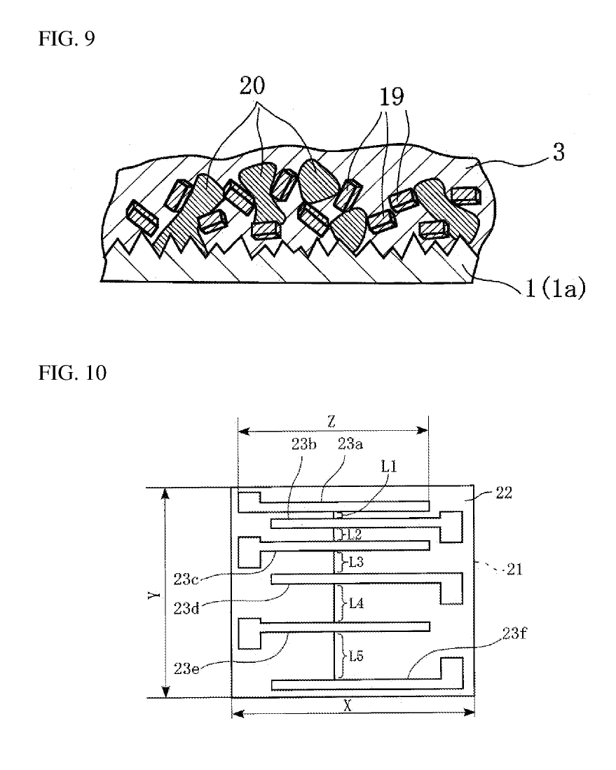

As shown in FIG. 10, a predetermined electrode pattern was prepared on the antireflection film, and the contact resistance Rc was determined by a TLM (Transmission Line Model) method.

That is, an antireflection film 22 having a film thickness of 0.1 μm was formed by the plasma enhanced chemical vapor deposition method (PECVD) on the entire surface of a polycrystal Si type semiconductor substrate 21 having a lateral X of 5.0 mm, a longitudinal Y of 5.0 mm, and a thickness T of 0.2 mm. In addition, in the Si type semiconductor substrate 21, an n-type Si type semiconductor layer is formed on the upper surface of a p-type Si type semiconductor layer.

Then, screen printing was carried out by using the above electroconductive paste to prepare an electroconductive film of 20 μm in thickness having a predetermined pattern. Next, each sample was put into an oven set at a temperature of 150° C., so as to dry the electroconductive film.

Thereafter, with use of a belt-type near infrared furnace (CDF7210 manufactured by Despatch Industries G.K.), the sample was fired at a maximum firing temperature of 750° C. in an ambient atmosphere by adjusting the transportation speed so that the sample passed between the entrance and the exit in about one minute to prepare samples of the sample Nos 1 to 11 on which electrodes 23a to 23f were formed.

Here, distances L1 to L5 of electrodes 23a to 23f were measured, and consequently the distance L1 between the electrodes 23a and 23b was 200 μm, the distance L2 between the electrodes 23b and 23c was 400 μm, the distance L3 between the electrodes 23c and 23d was 600 μm, the distance L4 between the electrodes 23d and 23e was 800 μm, and the distance L5 between the electrodes 23e and 23f was 1000 μm. Also, all the lengths Z of the electrodes were 3.0 mm.

Then, on each sample of the sample Nos 1 to 11, the contact resistance Rc was determined by using a TLM method.

This TLM method is widely known as a method of evaluating the contact resistance of a thin film sample, and a transmission line theory is used, and the contact resistance Rc is calculated considering the electrode and the semiconductor substrate under the electrode to be equivalent to the so-called transmission line circuit. That is, a mathematical formula (4) holds among the lengths Z of the electrodes 23a to 23f, a sheet resistance R_{SH} of an n-type Si type semiconductor layer, a distance L between electrodes, and resistance R between electrodes.

R=(L/Z)×R_{SH}+2Rc (4)

As is apparent from the mathematical formula (4), the resistance R between electrodes bears a linear relationship to the distance L between electrodes. Accordingly, 2Rc is determined by measuring each resistance R at a distance Ln (n=1 to 5) between electrodes, and extrapolating L to zero, and the contact resistance Rc can be calculated from the 2Rc.

Thus, in this Example, each resistance R at the distance Ln between electrodes was measured, and the contact resistance Rc was calculated on each sample of the sample Nos 1 to 11. In addition, the sheet resistance R_{SH} of an n-type Si type semiconductor layer can be calculated from the gradient of the straight line derived from the above mathematical formula (4) in an L (horizontal axis)-R (vertical axis) coordinate system. Here, the sheet resistance R_{SH} was 30 Ωcm.

Table 2 shows a kind of a glass frit, a D₅₀ diameter, a D₉₀ diameter, and contact resistance Rc of each sample of the sample Nos 1 to 11.

TABLE 2

| | | | | Contact |
|---|---|---|---|---|
| Sample | Kind of | D₅₀ diameter | D₉₀ diameter | resistance Rc |
| No. | Glass Frit | (μm) | (μm) | (Ω) |
| 1 | A | 0.8 | 2.1 | 1.54 |
| 2 | B | 0.8 | 2.7 | 1.59 |
| 3 | C | 0.8 | 2.7 | 1.98 |
| 4*¹⁾ | D | 0.8 | 2.7 | 3.51 |
| 5*¹⁾ | E | 0.8 | 2.7 | 4.41 |
| 6 | F | 0.8 | 2.7 | 1.62 |
| 7 | G | 0.8 | 2.7 | 2.44 |
| 8*¹⁾ | H | 0.8 | 2.7 | 3.62 |
| 9 | A | 0.8 | 2.7 | 1.51 |
| 10 | A | 0.8 | 4.9 | 1.88 |
| 11*¹⁾ | A | 0.8 | 6.2 | 3.25 |

*¹⁾indicates outside the scope of the present invention (claim 1)

In the sample No 4, the contact resistance Rc was as high as 3.51Ω. The reason for this is probably that since this sample used the glass frit D and a ratio B₂O₃/SiO₂ was 0.48 exceeding 0.4, the Ag powder was hardly deposited on the Si type semiconductor substrate 21, and glass accumulation at an interface was generated to impair the formation of electrical contact.

In the sample No 5, the contact resistance Rc was as high as 4.41Ω. The reason for this is probably that since this sample used the glass frit E and the molar content of Bi₂O₃ was 41.0 mol % exceeding 30 mol %, the softening point was as low as 511° C. to decrease glass viscosity, and therefore the flowability of the glass frit becomes too high, and consequently glass accumulation at an interface was generated.

In the sample No 8, the contact resistance Rc was as high as 3.62Ω. The reason for this is probably that since the glass frit H was used, the molar content of Bi₂O₃ is as small as 16.8 mol % and the softening point was as high as 582° C., the fire-through property was deteriorated.

On the other hand, in the sample No 11, the glass frit A was used, and the ratio B₂O₃/SiO₂ and the molar content of Bi₂O₃ satisfied the scope of the present invention, but the contact resistance Rc was as high as 3.25Ω. The reason for this is probably that the D₉₀ diameter was as large as 6.2 μm and the dispersibility of the glass frits was not sufficient, and therefore the glass accumulation at an interface was generated after firing.

On the contrary, in the sample Nos 1 to 3, 6, 7, 9 and 10, it was found that the contact resistance Rc was 1.51 to 2.44Ω and can be reduced to 3Ω or less, and a solar cell having high conversion efficiency can be prepared since the glass frits A to C, F and G, in which the ratio B₂O₃/SiO₂ was 0.4 or less, the molar content of Bi₂O₃ was 20 to 30 mol % and the D₉₀ diameter was less than 5 μm, were used.

### Example 2

A glass frit A having the same specification (D₅₀ diameter: 0.8 μm, D₉₀ diameter: 2.7 μm) as in the sample No 9 of Example 1 was prepared. Then, 83.0% by weight of an Ag powder, 4.6% by weight of ZnO, 2.1% by weight of the glass frit A, and 10.3% by weight of the organic vehicle were mixed, and the resulting mixture was mixed with a planetary mixer and then kneaded with a three roll mill to prepare electroconductive pastes of sample Nos 21 to 28. In addition, ZnO with a specific surface area of 3.4 to 15.6 m²/g was used as ZnO contained in the electroconductive paste.

Next, on the sample Nos 21 to 28, the contact resistance Rc was measured according to a TLM method by the same method/procedure as in [Example 1].

Also, on the sample Nos 21 to 28, the soldering property was evaluated according the following method.

That is, as with [Example 1], an antireflection film is formed on the surface of the semiconductor substrate, and then the electroconductive paste of each of the sample Nos 21 to 28 was applied by screen printing to prepare an electroconductive film. Thereafter, these samples were dried in an oven set at a temperature of 150° C., and then passed through a belt type near-infrared furnace, and fired at a maximum temperature of 780° C. in an ambient atmosphere to form a light-receiving surface electrode to prepare samples for measuring adhesive strength of the sample Nos 21 to 28. In addition, an outer dimension of the prepared light-receiving surface electrode was 50 mm long, 2 mm wide, and 20 μm in film thickness, and rectangle-shaped.

Then, with respect to each sample of these sample Nos 21 to 28, a solder ribbon was pressed against the surface of the electrode to be soldered by using a soldering iron heated to about 250° C., and thereafter the solder ribbon was pulled.

The soldering property was evaluated as follows: the case where the solder ribbon cannot be bonded to the surface of the electrode with a soldering iron was rated as a failure of soldering (x), the case where the solder ribbon was peeled off at the surface of the electrode in pulling the solder ribbon after bonding was rated as a possibility of soldering (Δ), and the case where the solder ribbon was not peeled off at the surface of the electrode even though pulling the solder ribbon after bonding was rated as a pass of soldering (◯).

Table 3 shows a specific surface area of ZnO, contact resistance Rc and a soldering property.

TABLE 3

| | Specific Surface | Contact | |
|---|---|---|---|
| | Area of ZnO | resistance Rc | Soldering |
| Sample No. | (m²/g) | (Ω) | Property |
| 21*²⁾ | 3.4 | 3.66 | ◯ |
| 22 | 6.6 | 1.51 | ◯ |
| 23 | 7.5 | 1.15 | ◯ |
| 24 | 8.3 | 1.06 | ◯ |
| 25 | 9.2 | 1.09 | ◯ |
| 26*⁴⁾ | 10.3 | 1.15 | Δ |
| 27*⁴⁾ | 12.1 | 0.99 | Δ |
| 28*³⁾ | 15.6 | 0.95 | X |

*²⁾indicates outside the scope of the present invention (claim 2)
*³⁾indicates outside the scope of the present invention (claim 3)
*⁴⁾indicates outside the scope of the present invention (claim 4)

In the sample No 21, the specific surface area of ZnO was as small as 3.4 m²/g, and therefore the contact resistance Rc was as high as 3.66Ω. The reason for this is probably that since the specific surface area is too small, a void is generated at the interface between a Si type semiconductor substrate 21 and an electrode 23 to make it easy for a melt glass to flow into between ZnO grains, and consequently a glass accumulation at an interface may be formed to increase contact resistance Rc.

On the other hand, in the sample No 28, the contact resistance Rc was good, but soldering could not be conducted since the specific surface area of ZnO was as excessively large as 15.0 m²/g or more.

Also, in the sample Nos 26 and 27, the contact resistance Rc was good, and the specific surface area of ZnO was 10.3 to 12.1 m²/g or more, and soldering could be conducted, but a solder ribbon was peeled off at the surface of the electrode in pulling it.

On the contrary, in the sample Nos 22 to 25, since the specific surface area of ZnO falls within a range of 6.5 to 9.5 m²/g, the contact resistance Rc could be reduced and a good soldering property could be achieved.

From the above, it was confirmed that the specific surface area of ZnO was 6.5 to 12.5 m²/g, and preferably 6.5 to 9.5 m²/g when the electroconductive paste contains ZnO.

### Example 3

ZnO (specific surface area: 8.3 m²/g) of the sample No 24 in Example 2 was prepared. Then, 83.0% by weight of an Ag powder, 4.6% by weight of ZnO, 2.1% by weight of glass frits having the composition shown in Table 4, and 10.3% by weight of the organic vehicle were mixed, and the resulting mixture was mixed with a planetary mixer and then kneaded with a three roll mill to prepare electroconductive pastes of sample Nos 31 to 37.

Next, on the sample Nos 31 to 37, the softening point and the contact resistance Rc were measured by the same method/procedure as in [Example 1].

Table 4 shows glass composition of a glass frit, B₂O₃/SiO₂, a softening point Ts, and contact resistance Rc.

TABLE 4

| | | | | | | | | B₂O₃/ | Softening | Contact |
|---|---|---|---|---|---|---|---|---|---|---|
| Sample | Glass Composition (mol %) | | | | | | | SiO₂ | Point | resistance |
| No. | SiO₂ | B₂O₃ | Bi₂O₃ | BaO | SrO | CaO | Al₂O₃ | (—) | Ts (° C.) | Rc (Ω) |
| 31 | 43.5 | 13.5 | 25.0 | 17.6 | 0 | 0 | 0.4 | 0.31 | 550 | 1.06 |
| 32*⁶⁾ | 43.5 | 13.5 | 25.0 | 0 | 17.6 | 0 | 0.4 | 0.31 | 556 | 1.88 |
| 33*⁶⁾ | 43.5 | 13.5 | 25.0 | 0 | 0 | 17.6 | 0.4 | 0.31 | 551 | 2.08 |
| 34*⁵⁾ | 56.4 | 18.2 | 25.0 | 0 | 0 | 0 | 0.4 | 0.32 | 560 | 2.93 |
| 35 | 47.8 | 14.8 | 25.0 | 12.0 | 0 | 0 | 0.4 | 0.31 | 543 | 1.13 |
| 36 | 51.3 | 15.5 | 25.0 | 7.8 | 0 | 0 | 0.4 | 0.30 | 556 | 0.89 |
| 37*⁷⁾ | 53.8 | 16.9 | 25.0 | 3.9 | 0 | 0 | 0.4 | 0.31 | 559 | 2.12 |

*⁵⁾indicates outside the scope of the present invention (claim 5)
*⁶⁾indicates outside the scope of the present invention (claim 6)
*⁷⁾indicates outside the scope of the present invention (claim 7)

The sample Nos 31 to 33 are samples formed by using BaO, SrO and CaO as an alkaline-earth metal oxide in the glass frit, and the sample No 34 is a sample not containing an alkaline-earth metal oxide.

As is apparent from the sample Nos 31 to 34, it is found that the sample Nos 31 to 33 containing an alkaline-earth metal oxide can reduce the contact resistance Rc as compared with the sample No 34 not containing an alkaline-earth metal oxide. In particular, BaO (sample No 31) could be confirmed to contribute to the reduction of contact resistance compared with other alkaline-earth metal oxides (sample Nos 32, 33).

The sample Nos 35 to 37 used BaO as an alkaline-earth metal oxide to vary the molar content in the glass frit.

It was confirmed that the sample Nos 35 and 36 containing BaO in an amount of 5 mol % or more can reduce the contact resistance Rc more than the sample No 37 containing BaO in an amount less than 5 mol %.

A solar cell having low contact resistance and high conversion efficiency can be realized by using a non-lead type electroconductive paste having a good fire-through property even when the electrode width of the light-receiving surface electrode is fine.

### DESCRIPTION OF REFERENCE SYMBOLS

1 Semiconductor substrate
2 Antireflection film
3 Light-receiving surface electrode (electrode)

1. An electroconductive paste comprising:
an electroconductive powder;
glass frit; and
an organic vehicle,
wherein the glass frit does not contain Pb and contains at least B, Bi and Si,
a molar ratio of B to Si is 0.4 or less,
a molar content of Bi in the glass frit is 20 to 30 mol %, and
a 90% cumulative grain diameter measured from a fine grain side in a cumulative grain size distribution of the glass frit is 5 μm or less.

2. The electroconductive paste according to claim 1, wherein the glass frit contains SiO₂, B₂O₃ and Bi₂O₃, the molar ratio of the B to the Si is 0.4 or less in terms of the SiO₂ and the B₂O₃, and the molar content of the Bi in the glass frit is 20 to 30 mol % in terms of the Bi₂O₃. (from claim 1)

3. The electroconductive paste according to claim 1, further comprising ZnO. (from new paragraph [0087])

4. The electroconductive paste according to claim 3, wherein the ZnO has a specific surface area of 6.5 m²/g or more. (from claim 2)

5. The electroconductive paste according to claim 3, wherein the ZnO has a specific surface area of 12.5 m²/g or less. (from claim 3)

6. The electroconductive paste according to claim 3, wherein the ZnO has a specific surface area of 9.5 m²/g or less. (from claim 4)

7. The electroconductive paste according to claim 3, wherein the ZnO is in an amount of 1 to 15 parts by weight with respect to 100 parts by weight of the electroconductive powder. (from new paragraph [0087])

8. The electroconductive paste according to claim 7, wherein the ZnO has a specific surface area of 6.5 m²/g or more.

9. The electroconductive paste according to claim 7, wherein the ZnO has a specific surface area of 12.5 m²/g or less.

10. The electroconductive paste according to claim 7, wherein the ZnO has a specific surface area of 9.5 m²/g or less.

11. The electroconductive paste according to claim 1, wherein the glass frit contains an alkaline-earth metal oxide.

12. The electroconductive paste according to claim 11, wherein the alkaline-earth metal oxide is BaO.

13. The electroconductive paste according to claim 11, wherein a content of the alkaline-earth metal oxide is 5 mol % or more.

14. The electroconductive paste according to claim 1, wherein the electroconductive paste is an Ag powder.

15. The electroconductive paste according to claim 1, wherein the glass frit is in an amount of 1 to 6 parts by weight with respect to 100 parts by weight of the electroconductive powder. (from new paragraph [0085])

16. A solar cell comprising:
a semiconductor substrate;
an antireflection film adjacent a first surface of the semiconductor substrate; and
an electrode penetrating through the antireflection film,
wherein the electrode is formed by sintering the electroconductive paste according to claim 1.

17. The solar cell according to claim 16, wherein the semiconductor substrate comprises a p-type semiconductor layer and an n-type semiconductor layer, the n-type semiconductor layer being the first surface of the semiconductor substrate. (from new paragraph [0048])

18. The solar cell according to claim 16, wherein the electrode comprises a plurality of finger electrodes electrically connected to a bus bar electrode. (from new paragraph [0052])

19. The solar cell according to claim 18, wherein the plurality of finger electrodes are disposed in parallel in a comb-teeth shape. (from new paragraph [0052])
